(19) United States
(12) Patent Application Publication
(10) Pub. No.: US 2026/0362781 A1
(43) Pub. Date: Nov. 12, 2026

(54) SEMICONDUCTOR DEVICES AND METHODS FOR MAKING SUCH

(71) Applicant: Taiwan Semiconductor Manufacturing Company, LTD., Hsinchu (TW)

(72) Inventors: Tsung-Lin Lee, Hsinchu (TW); Chih Chieh Yeh, Taipei (TW); Choh Fei Yeap, Hsinchu (TW)

(21) Appl. No.: 19/201,217

(22) Filed: May 7, 2025

(51) Int. Cl. H10D 84/01; H10D 30/00; H10D 30/01

(52) U.S. Cl. CPC H10D 84/0133; H10D 30/0195; H10D 30/507

(57) ABSTRACT

Several different embodiments of semiconductor devices and methods for making such devices with additional control of electrical junctions are disclosed. Dopants are incorporated, or surface inversion is induced by the use of polar compounds or surface treatments that reduce the bandgap. Variations are reduced, and yield and reliability are improved.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

An integrated circuit is made of large numbers of transistors. A field-effect transistor is generally composed of a substrate on which an electrically conductive gate electrode controls the flow of current between a source electrode and a drain electrode. An electrically insulating gate dielectric layer separates the gate electrode from the source and drain electrodes. A semiconductor layer bridges the source and drain electrodes, and is in contact with the gate dielectric layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a first embodiment of a transistor of the present disclosure, in accordance with some embodiments of the present disclosure. A cap is formed on the semiconducting layers/channels. A magnified cross-sectional view is also present as FIG. 1B.

FIG. 2 is a flow chart illustrating a first method for making an intermediate transistor structure, in accordance with some embodiments.

FIG. 3 is a perspective view of one embodiment of the intermediate transistor structure.

FIG. 4 is a Y-axis cross-sectional view of the intermediate transistor structure after recesses are formed in the sacrificial layers.

FIG. 5 is a flow chart illustrating one method for making a transistor, in accordance with some embodiments. Here, caps are formed on the semiconducting layers/channels.

FIG. 6 is a side cross-sectional view of the substrate after caps are formed on the exposed surfaces of the semiconducting layers within the S/D trenches.

FIG. 7 is a side cross-sectional view of the substrate after inner spacers are formed.

FIG. 8 is a side cross-sectional view of the substrate of one embodiment, after counter-doping is performed at the bottom of the S/D trenches.

FIG. 9 is a side cross-sectional view of the substrate of another embodiment, after the S/D trenches are leveled and counter-doping is performed.

FIG. 10 is a side cross-sectional view of the substrate after formation of the S/D regions.

FIG. 11A is a cross-sectional view of a second embodiment of a transistor of the present disclosure, in accordance with some embodiments of the present disclosure. Surface layers are formed on the semiconducting layers in the area along the inner spacers.

FIG. 11B is a magnified cross-sectional view of the rectangle in FIG. 11A, showing a P-channel device where the surface layer comprises a polar compound.

FIG. 11C is a magnified cross-sectional view of the rectangle in FIG. 11A, showing an N-channel device where the surface layer comprises a polar compound.

FIG. 11D is a magnified cross-sectional view of the rectangle in FIG. 11A, showing an N-channel device where the surface layer comprises a positively charged material.

FIG. 11E is a magnified cross-sectional view of the rectangle in FIG. 11A, showing a P-channel device where the surface layer comprises a negatively charged material.

FIG. 12 is a flow chart illustrating another method for making a transistor, in accordance with some embodiments. Here, surface layers of polar compounds or materials with a net charge are formed on the semiconducting layers/channels.

FIG. 13 is a side cross-sectional view of the substrate after a surface layer or film is deposited upon the sides of the S/D trenches.

FIG. 14 is a side cross-sectional view of the substrate after inner spacers are formed.

FIG. 15 is a side cross-sectional view of the substrate after spacer etching is performed and the S/D trenches are leveled.

FIG. 16A is a cross-sectional view of a third embodiment of a transistor of the present disclosure, in accordance with some embodiments of the present disclosure. Surface layers are formed on the semiconducting layers from a material that reduces the bandgap of the semiconducting layers. Here, the surface layer is also present between the inner spacers and the volumes where the gate electrode will be formed.

FIG. 16B is a cross-sectional view of a third embodiment of a transistor of the present disclosure, in accordance with some embodiments of the present disclosure. Surface layers are formed on the semiconducting layers from a material that reduces the bandgap of the semiconducting layers. Here, the surface layers are only present on the surfaces of the semiconducting layers.

FIG. 17 is a flow chart illustrating another method for making a transistor, in accordance with some embodiments. Here, surface layers are formed from a bandgap-reducing material.

FIG. 18 is a side cross-sectional view of the substrate after a surface layer or film is formed by thermal annealing in the presence of a gas.

FIG. 19 is a side cross-sectional view of the substrate after inner spacers are formed.

FIG. 20 is a side cross-sectional view of the substrate after spacer etching is performed and the S/D trenches are leveled.

FIG. 21 is a side cross-sectional view of the substrate after a surface layer or film is formed by epitaxy on the exposed surfaces of the semiconducting layers.

FIG. 22 is a side cross-sectional view of the substrate after inner spacers are formed.

FIG. 23 is a side cross-sectional view of the substrate after spacer etching is performed and the S/D trenches are leveled.

FIG. 24 is a flow chart illustrating a method for completing the formation of a Gate-All-Around (GAA) transistor after the intermediate transistor structure is processed, in accordance with some embodiments.

FIG. 25A is a perspective view of a GAA transistor after the method of FIG. 24.

FIG. 25B is a Y-axis cross-sectional view along line B-B of FIG. 25A. FIG. 25C is an X-axis cross-sectional view along line C-C of FIG. 25A, through a gate electrode.

FIG. 26 is a flow chart illustrating a method for making a fin field effect transistor, or FinFET, with a surface layer, in accordance with some embodiments.

FIG. 27A is a Y-axis cross-sectional view of a FinFET with a surface layer, in accordance with some embodiments. FIG. 27B is a Z-axis cross-sectional view of the FinFET though line B-B of FIG. 27A. FIG. 27C is an X-axis cross-sectional view of the FinFET though lines C-C and D-D of FIG. 27A.

FIG. 28 is a flow chart illustrating a method for making a planar transistor with a surface layer, in accordance with some embodiments.

FIG. 29 is a Y-axis cross-sectional view of a planar transistor with a surface layer, in accordance with some embodiments.

FIG. 30 is a flow chart illustrating a method for using a transistor, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value, as understood and interpreted by one of ordinary skill in the art. When used with a range, “about” also discloses the range defined by the absolute values of the two endpoints, e.g. “about 2 to about 4” also discloses the range “from 2 to 4.” For example, the term “about” may refer to plus or minus 10% of the indicated number.

The present disclosure refers to temperatures for certain process steps. It is noted that these generally refer to the temperature at which the heat source (e.g. furnace) is set, and do not necessarily refer to the temperature which must be attained by the material being exposed to the heat.

The present disclosure relates to structures which are made up of different layers. When the terms “on” or “upon” or “over” are used with reference to two different layers (including the substrate), they indicate merely that one layer is on or upon or over the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to methods for producing semiconductor devices, such as transistors, with controlled electrical junctions. Traditional junctions are formed and controlled by either dopant implantation or by in-situ doped epitaxy of the S/D regions. As devices shrink in size, pitch, and scale, especially in three-dimensional devices such as FinFETs or Gate-All-Around (GAA) transistors, such methods may cause fluctuations in doping and variations due to etching, which cause variations in performance and impact yield and reliability. In the present disclosure, the electrical junctions are formed by first incorporating dopants or inducing surface inversion through charge or surface treatment, and then by forming the source/drain (S/D) regions. Surface layers may be formed upon surfaces between the semiconducting layer(s) and the S/D regions, or between the semiconducting layer(s) and the gate electrode.

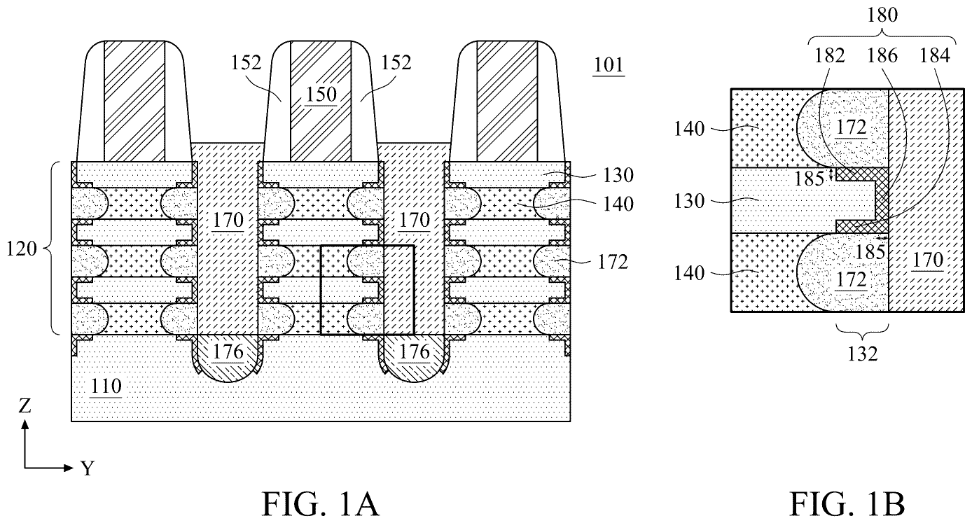

FIG. 1A is a cross-sectional view of a first embodiment of a transistor 101 of the present disclosure, in accordance with some embodiments of the present disclosure. A cap is formed on the semiconducting layers/channels. A magnified cross-sectional view of the dashed box is also present as FIG. 1B.

Here, the transistor 101 is a Gate-All-Around (GAA) transistor. The transistor 101 is present upon a semiconducting substrate 110. Three semiconducting stacks 120 are shown, which are formed by alternating layers of semiconducting layers 130 and sacrificial layers 140. In this particular example, three semiconducting layers and three sacrificial layers are illustrated, although generally any desired number of these layers may be present. Located above each semiconducting stack 120 is a dummy gate 150. A gate spacer 152 is also present around the dummy gate.

Two S/D regions 170 are also present. The S/D regions are present on opposite sides of each semiconducting stack 120. Inner spacers 172 are present that electrically isolate the S/D regions 170 from the sacrificial layers 140, which will eventually be replaced with a gate electrode. In addition, the S/D regions 170 are illustrated as being formed upon a base layer 176, which is used to control the depth of the current flow. For example, in some embodiments, it is desired that electrical current flows only through the semiconducting layers 130, and not through the substrate 110.

Referring now to the magnified view of FIG. 1B, the end 132 of one semiconducting layer is shown. This end of the semiconducting layer is electrically connected to a S/D region 170. Inner spacers 172 are visible above and below the semiconducting layer. A cap 180 is present at the end of the semiconducting layer. The cap is illustrated as having three sides. One side 182 is present on an upper surface of the semiconductor layer, below an inner spacer. A second side 184 is present on a lower surface of the semiconductor layer, above an inner spacer. A third side 186 is present between the semiconducting layer and an S/D region 170. In particular embodiments, the sides of the cap have a thickness 185 of about 0.5 nanometers to about 2 nanometers. Other values and ranges are also within the scope of this disclosure.

The cap comprises an n-type dopant or a p-type dopant, depending on the construction of the transistor. The dopant may be diffused into the semiconducting layer to form a dopant gradiant which is highest near the caps on the sides of the semiconducting layer.

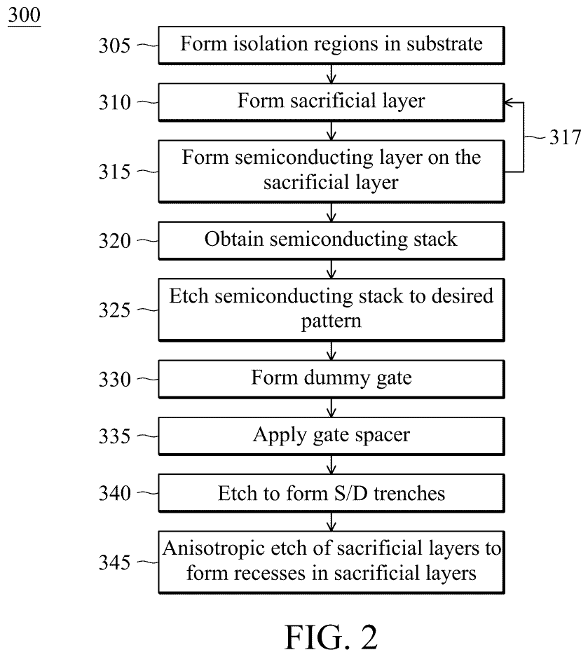

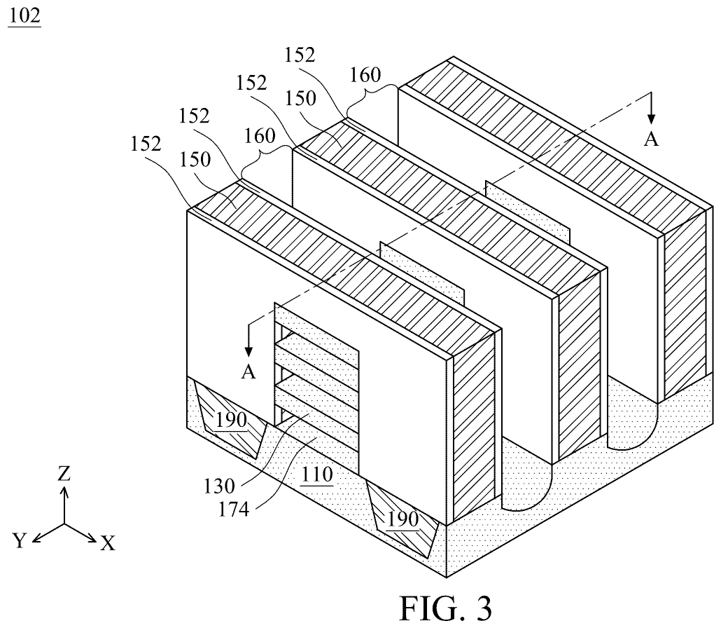

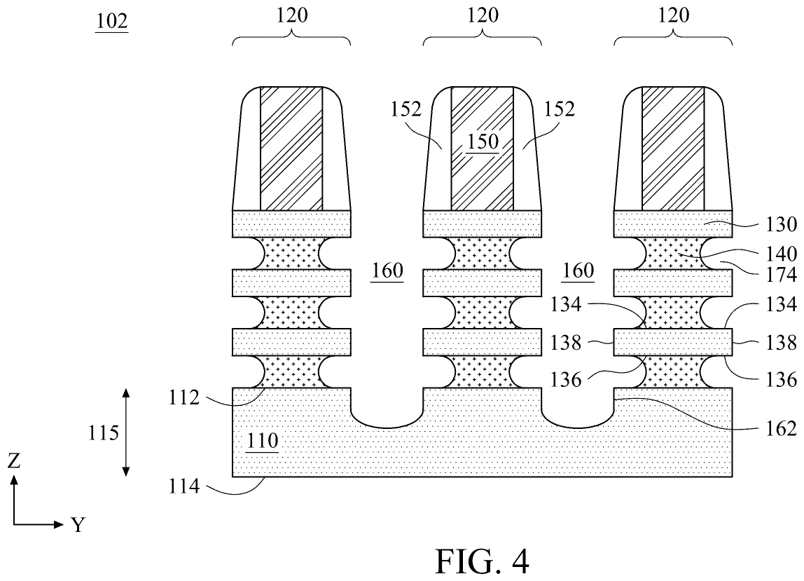

FIG. 2 is a flow chart illustrating a first method 300 for making an intermediate transistor structure 102, in accordance with some embodiments. FIG. 3 is a perspective view of one embodiment of the intermediate transistor structure. FIG. 4 is a Y-axis cross-sectional view through line A-A of FIG. 3. In particular, the intermediate transistor structure illustrated here is for making a GAA transistor. While the method steps are discussed below in terms of forming a single structure, such discussion should also be broadly construed as applying to the concurrent formation of multiple structures, and can be suitably adapted to form other transistors or devices. Other structures may also be concurrently formed. It is noted that not all steps described in the flow chart are required, and not all method steps are described in the flow chart.

Initially, FIG. 3 and FIG. 4 show the substrate 110 upon which the transistors will be formed. The substrate 110 may be, for example, a wafer made of a semiconducting material. Semiconductor materials can include silicon, for example in the form of crystalline Si. In alternative embodiments, the substrate can be made of other elementary semiconductors such as germanium, silicon carbide (SiC), silicon germanium, or silicon germanium carbide. The substrate 110 may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. As labeled in FIG. 4, the substrate 110 has an upper surface 112 and a lower surface 114, and has a thickness 115 between these two surfaces.

In step 305 of FIG. 2, one or more isolation regions 190 are formed in the substrate 110 to define an active region of the substrate. The isolation regions may be, for example, shallow trench isolation (STI) regions or deep trench isolation (DTI) regions. The isolation regions are formed by patterning the substrate, etching one or more isolation trenches, and filling the trenches with a dielectric material to obtain the isolation regions. The dielectric material in the isolation region is commonly silicon dioxide, although other dielectric materials can also be used such as undoped polysilicon, silicon oxide (e.g., SiO₂), silicon nitride, silicon oxynitride, fluoride-doped silicate glass, or other low-k dielectric material. The deposition can be done using physical vapor deposition (PVD) or chemical vapor deposition (CVD) or spin-on processes known in the art, or can be grown via oxidation. If desired, the dielectric material can be deposited to a level above that of the substrate upper surface, then recessed back down to the desired height. Isolation regions may be formed in both the X-axis and the Y-axis around the active region.

In step 310 of FIG. 2, a sacrificial layer 140 is formed upon the substrate. In step 315, a semiconducting layer 130 is formed upon the sacrificial layer. These layers can be made using CVD, atomic layer deposition (ALD), molecular beam epitaxy (MBE), liquid phase epitaxy (LPE), vapor phase epitaxy (VPE), or any other appropriate process. Steps 310-315 can be repeated to create as many semiconducting layers or channels as desired, with a sacrificial layer between each semiconducting channel, indicated by step 317. A semiconducting stack 120 is thus obtained, as indicated by step 320.

The semiconducting layer is usually made of the same material as the substrate, such as for example silicon. The sacrificial layers 140 can be made of any suitable material which can be selectively etched in comparison to the other materials that will be used in the transistor, such as for example SiGe, SiN, or SiON.

Next, in step 325 of FIG. 2, etching is performed to shape the semiconducting stack 120 to obtain a desired pattern or shape. This may be done, for example, by forming a mask over the semiconducting stack, then etching each layer using suitable etchants. The mask is then removed.

If desired, a dummy gate oxide layer can be formed upon the substrate. This can be done using ALD, CVD, or other deposition processes. Next, in step 330 of FIG. 2, dummy gates 150 are formed. Then, in step 335, gate spacers 152 may be applied around the dummy gates. Next, in step 340, etching is performed to form S/D trenches 160. As illustrated here, the S/D trenches extend into the substrate 110, although this is not required.

Then, in step 345 of FIG. 2, the exposed surfaces of the sacrificial layers within the S/D trenches are anisotropically etched to remove portions of the sacrificial layers and form recesses 174. The resulting structure 102 is shown in FIG. 3.

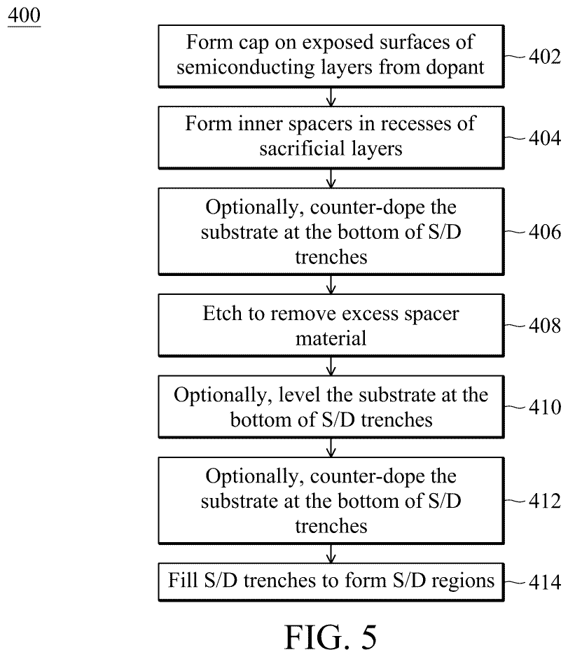

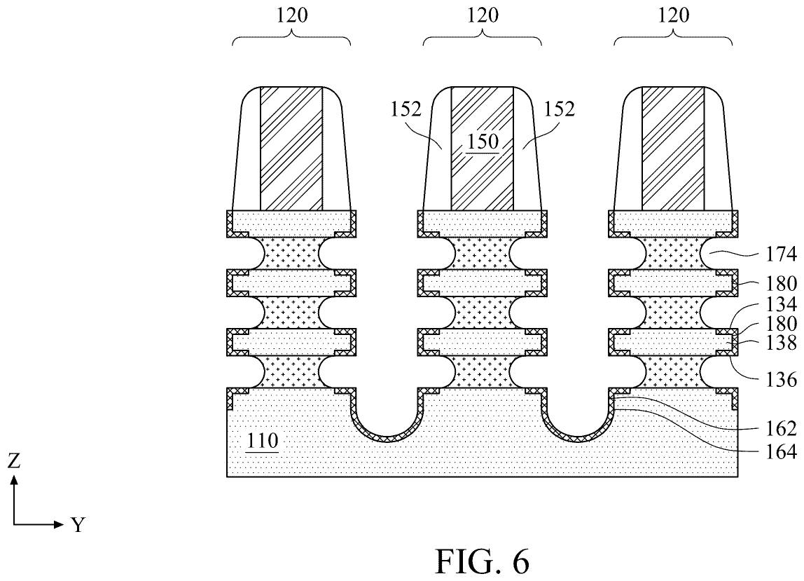

FIG. 5 is a flow chart illustrating one method 400 for making a transistor, in accordance with some embodiments. In particular, a GAA transistor is made in which caps are formed on the semiconducting layers. The method starts with the intermediate structure of FIG. 3 and FIG. 4, and some steps of the method are also illustrated in FIGS. 6-10. These figures provide different views for better understanding. While the method steps are discussed below in terms of forming a single transistor, such discussion should also be broadly construed as applying to the concurrent formation of multiple structures, and can be suitably adapted to form other transistors or devices. Other structures may also be concurrently formed. It is noted that not all steps described in the flow chart are required, and not all method steps are described in the flow chart.

Initially, referring back to the structure of FIG. 4, the semiconducting layers 130 have exposed surfaces within the S/D trenches. For example, the recesses 174 in the sacrificial layers expose upper surfaces 134 and lower surfaces 136 of the semiconducting layers. Side surfaces 138 of the semiconducting layers are also exposed within the S/D trenches 160. In addition, the lower surfaces 162 of the S/D trenches within the substrate are also exposed.

Continuing, in step 402 of FIG. 5 and as illustrated in FIG. 6, a cap 180 is formed on the exposed surfaces 134, 136, 138 of the semiconducting layers. The cap comprises an n-type dopant or a p-type dopant. A doped layer 164 is also formed on the lower surfaces 162 of the S/D trenches 160. Some of the sides or surfaces of the caps may also be described as being located within the recesses 174 in the sacrificial layers 140.

Common n-type dopants for silicon may include phosphorus (P), arsenic (As), bismuth (Bi), or tantalum (Ta). Common p-type dopants for silicon may include boron (B), aluminum (Al), gallium (Ga), or indium (In). Different dopants may be used, depending on the material that is used to form the semiconducting layers. For example, in gallium arsenide, n-type dopants may include tin (Sn), silicon (Si), or titanium (Ti). In gallium arsenide, p-type dopants may include beryllium (Be), zinc (Zn), chromium (Cr), silicon (Si), or germanium (Ge). In gallium phosphide, n-type dopants may include tellurium (Te), selenium (Se), sulfur(S), or oxygen (O). In gallium phosphide, p-type dopants may include zinc (Zn), magnesium (Mg), or tin (Sn). In cadmium telluride, n-type dopants may include indium (In), aluminum (Al), fluorine (F), chlorine (Cl), bromine (Br), or iodine (I). In cadmium telluride, p-type dopants may include (P), lithium (Li), or sodium (Na). In cadmium sulfide, n-type dopants may include (Ga), fluorine (F), chlorine (Cl), bromine (Br), or iodine (I). In cadmium sulfide, p-type dopants may include lithium (Li) or sodium (Na).

At least two different methods for forming the cap are contemplated. The first method is by thermal treatment in the presence of a first gas containing the dopant. Examples of such gases may include, for example, B₂H₆ or PH₃. In particular embodiments, the thermal treatment occurs at a temperature of about 600 °C to about 900 °C, including from about 650 °C to about 750 °C. The thermal treatment may be performed for a time period ranging from about 20 seconds to about 2 minutes. Other values and ranges for these parameters are also within the scope of this disclosure.

The second method is by epitaxy in the presence of a first gas containing the dopant and a second gas that contains silicon. Examples of such silicon-containing gases or silicon precursors may include, but are not limited to, tetraethyl orthosilicate (TEOS), silane (SiH₄), trimethylsilane, tetramethylsilane, and hexachlorodisilane (HCDS). The molar ratio between the first gas and the second gas may be varied as desired to obtain the desired dopant concentration. In particular embodiments, the epitaxy occurs at a temperature of about 600 °C to about 900 °C, including from about 650 °C to about 750 °C The thermal treatment may be performed for a time period ranging from about 20 seconds to about 2 minutes. Other values and ranges for these parameters are also within the scope of this disclosure.

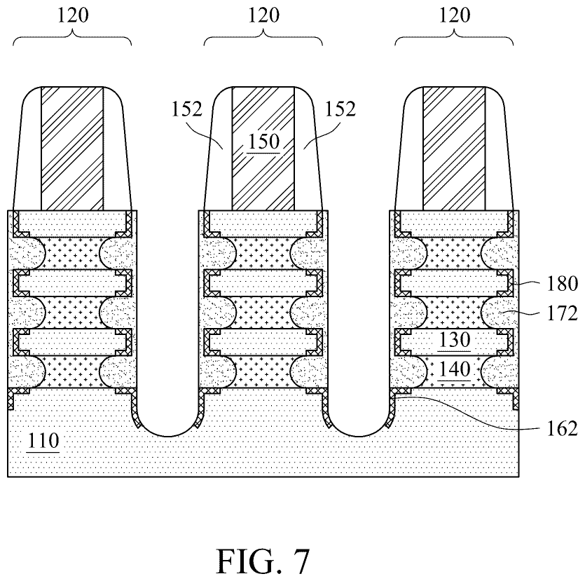

Then, in step 404 of FIG. 5 and as illustrated in FIG. 7, inner spacers 172 are formed within the recesses in the sacrificial layers 140. The inner spacers are formed from a dielectric material. The dielectric material can be a low-k or high-k dielectric material, as desired, and may be formed by any suitable deposition process, such as ALD. As illustrated here, the material used to form the inner spacers also covers the sides of the semiconductor layers in the S/D trenches. The deposition process can usually be controlled so as to avoid deposition into the lower surfaces 162 within the substrate 110.

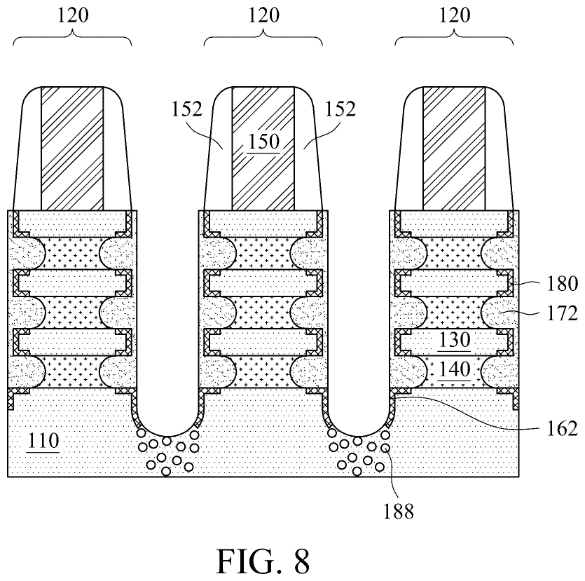

If desired, in optional step 406 of FIG. 5 and as illustrated in FIG. 8, the substrate 110 is counter-doped at the bottom of the S/D trenches 160. The counter-dopant is indicated with reference numeral 188. This is done to provide a neutral charge below the S/D region and reduce or prevent current leakage. The counter-doping may be performed by ion implantation or other suitable methods. Briefly, in ion implantation, an ion implanter is used to implant atoms into a silicon crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the counter-dopant can be deposited, following by annealing in which the counter-dopant reacts with the underlying exposed silicon.

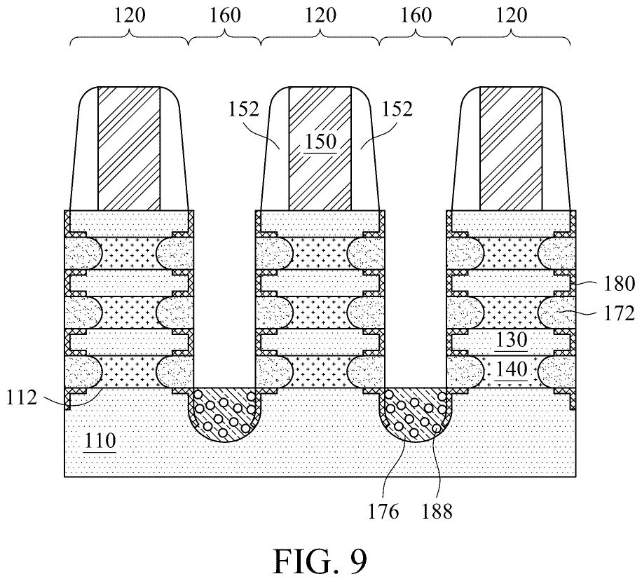

Next, in step 408 of FIG. 5 and as illustrated in FIG. 9, etching is performed within the S/D trenches 160 to remove excess inner spacer material (which is a dielectric) from the surfaces of the semiconducting layers within the S/D trenches 160. This may be done, for example, by etching or other suitable process.

If desired, in optional step 410 of FIG. 5 and as illustrated in FIG. 9, the substrate may be leveled at the bottom of the S/D trenches 160. Put another way, material is deposited into the S/D trenches to fill the portion of the S/D trenches that may extend below the upper surface 112 and into the substrate. This may be done, for example, by epitaxy. The material used to level the substrate corresponds to the base layer 176. In optional step 412, the substrate 110 may be counter-doped 188 at the bottom of the S/D trenches 160. Steps 410 and 412 may be performed concurrently if desired, for example by epitaxy in the presence of a third gas containing the counter-dopant and a fourth gas that contains silicon (or other appropriate material for the substrate). The resulting structure is shown in FIG. 9. In particular embodiments, either step 406 is performed, or step 412 is performed, to counter-dope the substrate below the S/D trenches 160. The cross-section of FIG. 1 illustrates an example where the substrate is leveled in step 410, but counter-doping is not performed.

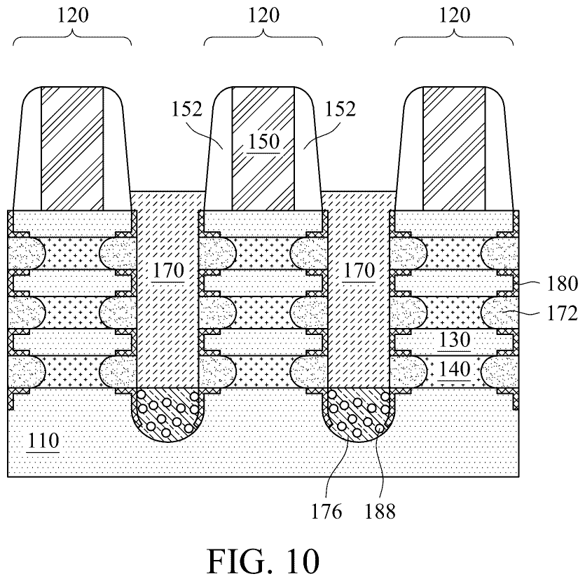

Finally, in step 414 of FIG. 5 and as illustrated in FIG. 10, the S/D trenches are filled to form S/D regions or electrodes 170. This is typically done by epitaxy in the presence of a fifth gas containing a dopant and a sixth gas that contains silicon (or other appropriate material for forming an electrode). The resulting structure is shown in FIG. 10.

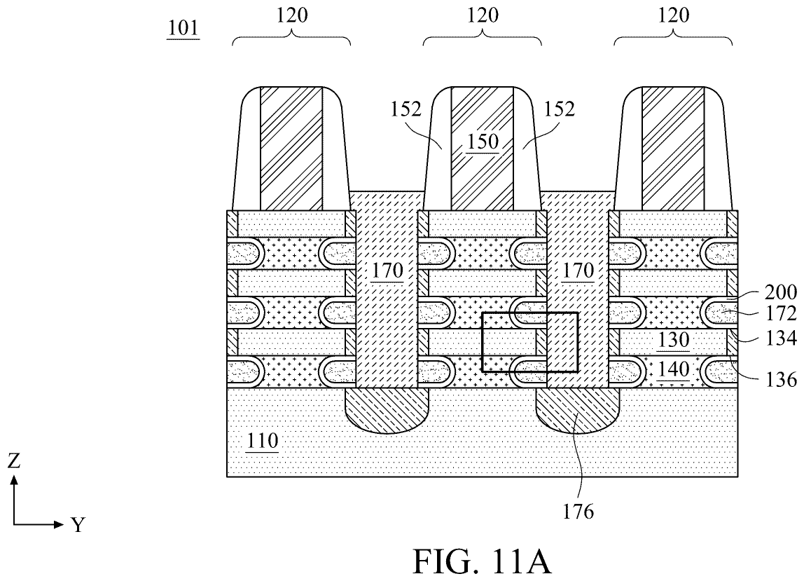

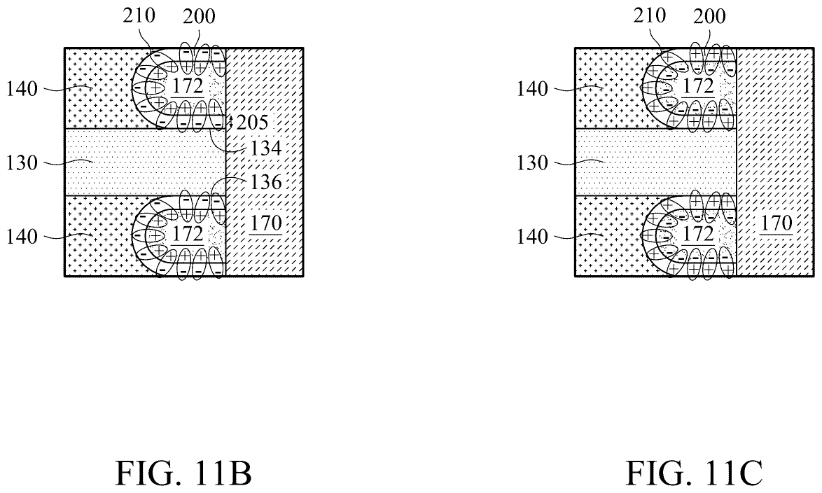

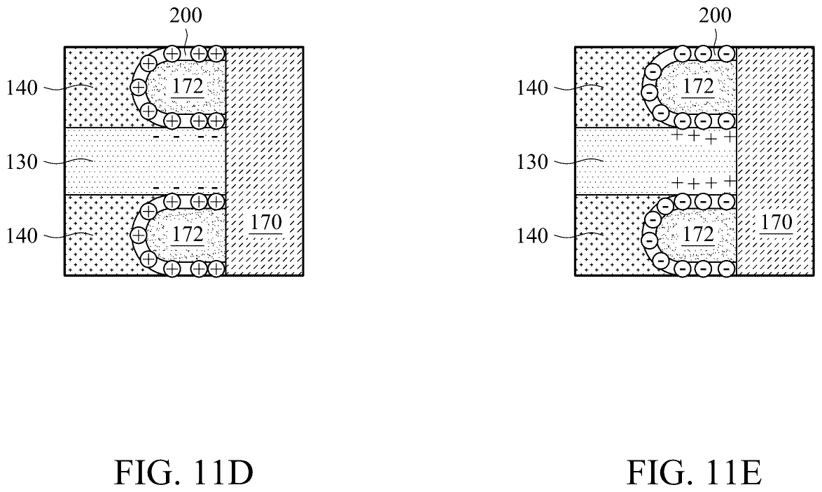

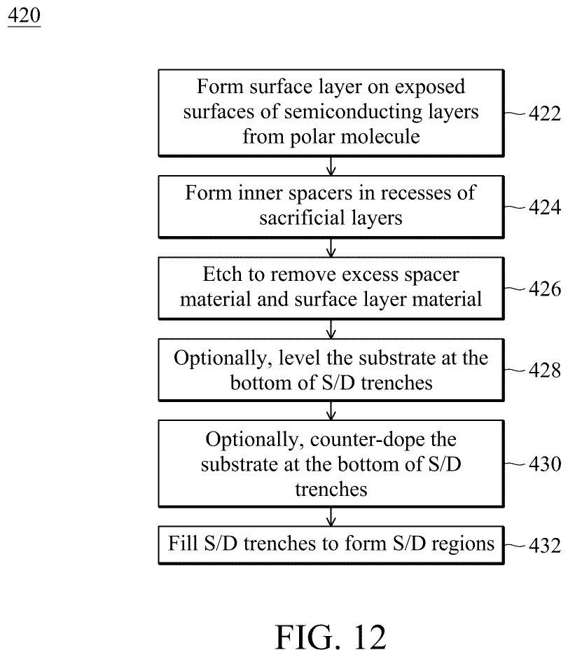

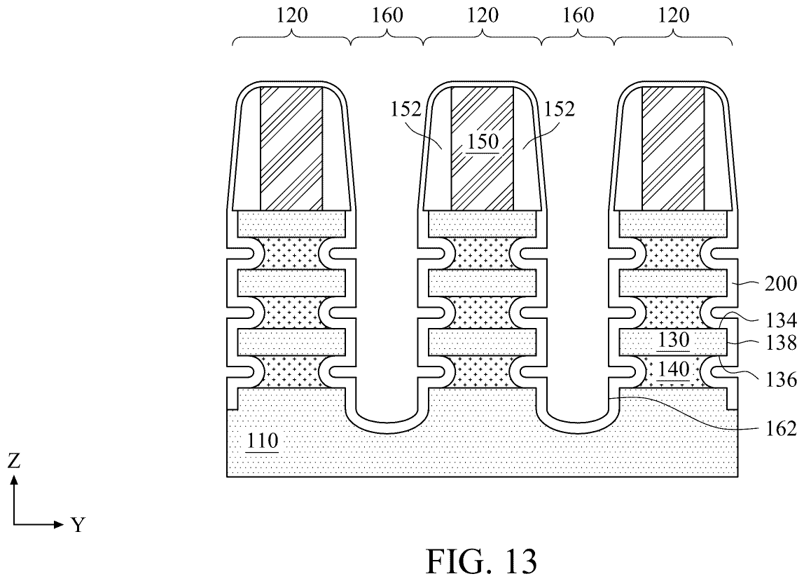

FIG. 11A is a Y-axis cross-sectional view of a second embodiment of a transistor 101 of the present disclosure, in accordance with some embodiments of the present disclosure. Here, surface layers are formed on the semiconducting layers/channels. Magnified cross-sectional views are also presented in FIGS. 11B-11E.

Referring first to FIG. 11A, the transistor 101 is illustrated here as a GAA transistor. The transistor includes a substrate 110, semiconducting stacks 120 formed by alternating layers of semiconducting layers 130 and sacrificial layers 140, inner spacers 172, dummy gates 150, gate spacers 152, a leveled substrate 110 with base layers 176, and S/D regions 170 as previously described. In FIG. 11A, the surface layers 200 are shown as surrounding three sides of the inner spacers 172 and contacting the sacrificial layers 140. The surface layer is missing from the side of the inner spacers that contacts the S/D regions 170. Surface layers 200 are present along upper surfaces 134 and lower surfaces 136 of the semiconducting layers.

Referring first to FIG. 11B, generally, in particular embodiments, the surface layer 200 may have a thickness 205 of about 0.5 nanometers to about 2 nanometers. Other values and ranges are also within the scope of this disclosure. As illustrated here, the upper surface 134 and the lower surface 136 of the end of the semiconducting layer 130 are in direct contact with the surface layer 200. In addition, the sacrificial layer 140 directly contacts the surface layer 200. The surface layer is not located between the inner spacer 172 and the S/D region 170.

Next, in some embodiments, the surface layers 200 comprise a polar compound, or in other words the compound has an electric dipole moment. This can arise due to the non-uniform distribution of positive and negative charges within the compound, e.g. due to very different electronegativities of the atoms. Such polar compounds will remain fixed in a specific location, and will not diffuse into the semiconducting layer during subsequent processing or treatment.

In FIG. 11B, the semiconducting layer 130 acts as a P-channel. The polar compound 210 is illustrated here with its negative pole adjacent the semiconducting layer. Examples of polar compounds suitable for use in the surface layer of a P-channel include oxides and nitrides that include an atom selected from the group consisting of aluminum, zinc, titanium, boron, gallium, indium, and thallium. Particular examples may include titanium dioxide (TiO₂), aluminum oxide (Al₂O₃), aluminum nitride (AlN), and zinc oxide (ZnO).

In FIG. 11C, the semiconducting layer 130 acts as an N-channel. The polar compound 210 is illustrated here with its positive pole adjacent the semiconducting layer. Examples of polar compounds suitable for use in the surface layer of an N-channel include oxides and nitrides that include a lanthanide atom. Specific examples may include lanthanum oxide (La₂O₃), cerium oxide (CeO₂, Ce₂O₃, or Ce₃O₄), and praseodymium oxide (PrO₂, Pr₂O₃).

In some other embodiments, the surface layers 200 are formed from a material having a net positive or negative charge. This can occur, for example, due to dangling bonds in the material, such as K-centers. However, such materials may not have an electric dipole moment.

In FIG. 11D, the semiconducting layer 130 acts as an N-channel. The surface layer 200 is illustrated here as a material having a net negative charge. Examples of such materials include nitrides, oxynitrides, or carbonitrides that include a lanthanide atom.

In FIG. 11E, the semiconducting layer 130 acts as a P-channel. The surface layer 200 is illustrated here as a material having a net positive charge. Examples of such materials include nitrides, oxynitrides, or carbonitrides that include silicon, boron, aluminum, gallium, indium, or thallium. For example, the surface layer may be made from silicon nitride (SiN), silicon oxynitride (SiON), or silicon carboxynitride (SiCON).

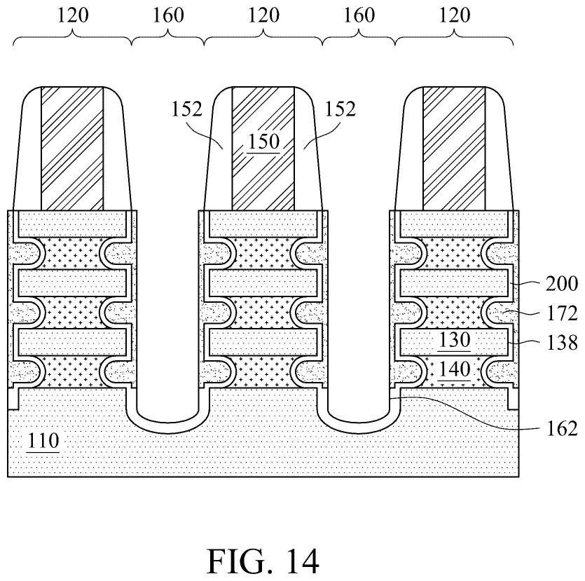

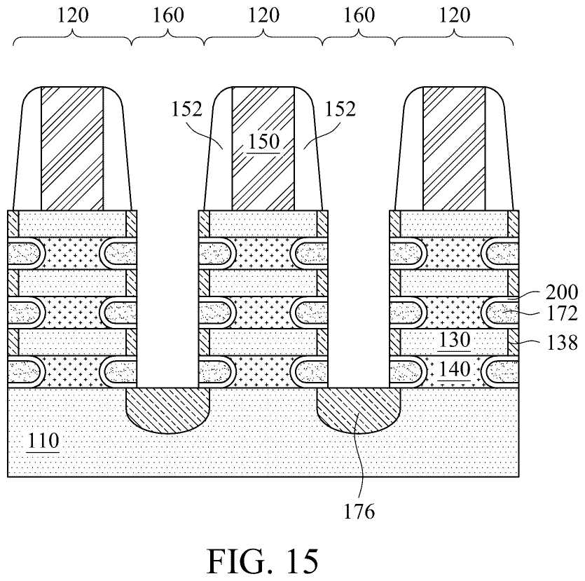

FIG. 12 is a flow chart illustrating another method 420 for making a transistor, in accordance with some embodiments. In particular, a GAA transistor is made in which surface layers are formed on the semiconducting layers. The method starts with the intermediate structure of FIG. 3 and FIG. 4, and some steps of the method are also illustrated in FIGS. 13-15. These figures provide different views for better understanding. While the method steps are discussed below in terms of forming a single transistor, such discussion should also be broadly construed as applying to the concurrent formation of multiple structures, and can be suitably adapted to form other transistors or devices. Other structures may also be concurrently formed. It is noted that not all steps described in the flow chart are required, and not all method steps are described in the flow chart.

Initially, in step 422 of FIG. 12 and as illustrated in FIG. 13, surface layers 200 are formed on the exposed surfaces 134, 136, 138 of the semiconducting layers 130. This may be done, for example, using CVD (particularly plasma-enhanced CVD) or ALD. The polar molecule or material having a net positive or negative charge is thus produced. As illustrated here, the surface layers 200 are formed as a thin film on the upper surface 134, lower surface 136, and side surfaces 138 at the ends of the semiconducting layers 130. The surface layers 200 are also formed on the other exposed surfaces, including over the gate spacers 152, the sacrificial layers 140, and the lower surfaces 162 of the S/D trenches 160.

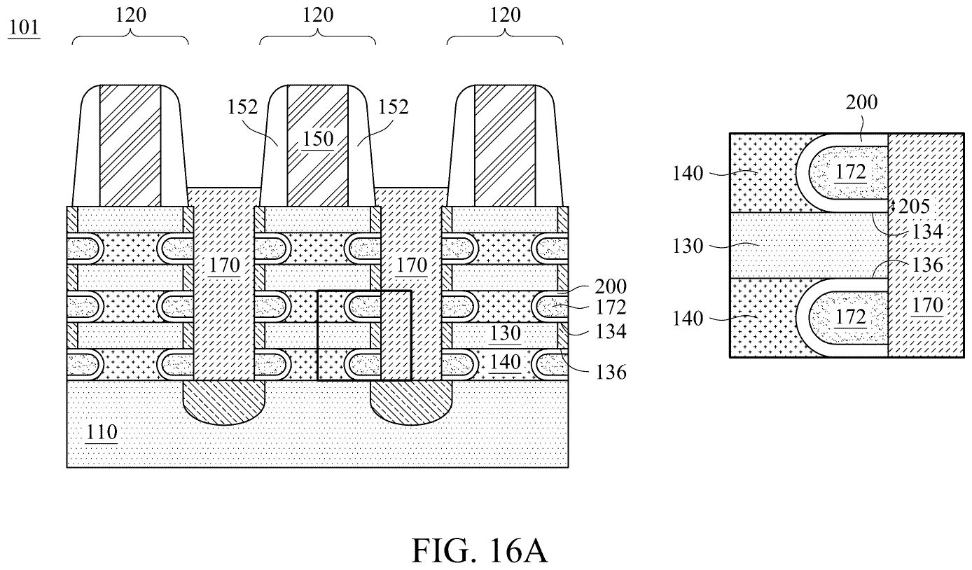

Then, in step 424 of FIG. 12 and as illustrated in FIG. 14, inner spacers 172 are formed within the recesses in the sacrificial layers 140. Again, the inner spacers are formed from a dielectric material. The dielectric material can be a low-k or high-k dielectric material, as desired, and may be formed by any suitable deposition process, such as ALD. As illustrated here, the material used to form the inner spacers also covers the sides 138 of the semiconductor layers. It is noted that in embodiments where the surface layer 200 is also a dielectric material, the inner spacer may be the same or a different dielectric material.

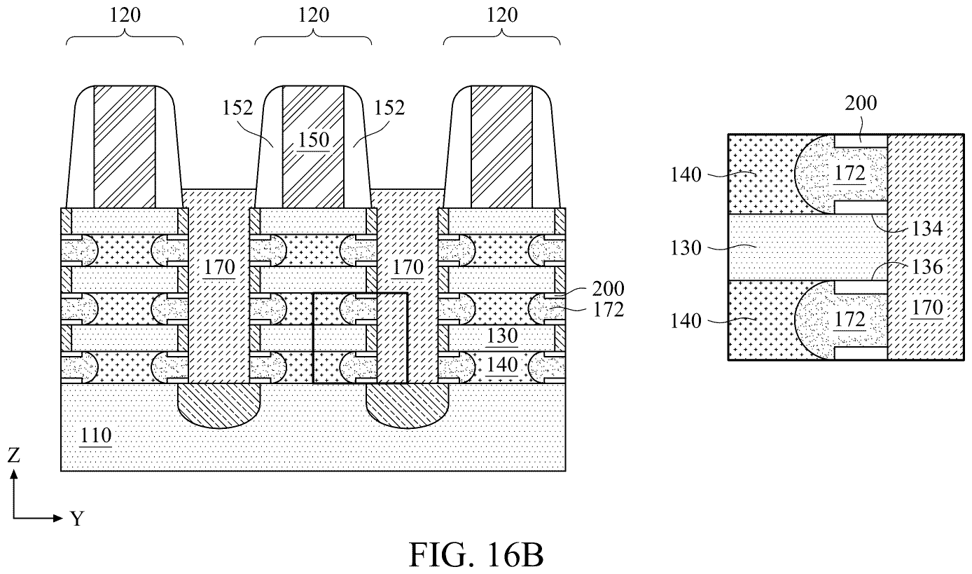

Next, in step 426 of FIG. 12 and as illustrated in FIG. 15, etching is performed within the S/D trenches 160 to remove excess inner spacer material and surface layer material from the surfaces 138 of the semiconducting layers within the S/D trenches 160. This may be done, for example, by etching or other suitable process. Material may also be removed from the lower surfaces 162.

If desired, in optional step 428 of FIG. 12 and as illustrated in FIG. 15, the substrate may be leveled at the bottom of the S/D trenches 160 by addition of a base layer 176. This may be done, for example, by epitaxy. In optional step 430, the substrate 110 may be counter-doped at the bottom of the S/D trenches 160. Steps 410 and 412 may be performed concurrently if desired, for example by epitaxy in the presence of a third gas containing the counter-dopant and a fourth gas that contains silicon (or other appropriate material for the substrate). The structure of FIG. 15 is not counter-doped.

Finally, in step 432 of FIG. 12, the S/D trenches are filled to form S/D regions 170. This is typically done by epitaxy in the presence of a fifth gas containing a dopant and a sixth gas that contains silicon (or other appropriate material for forming an electrode). The resulting structure is shown in FIG. 11A.

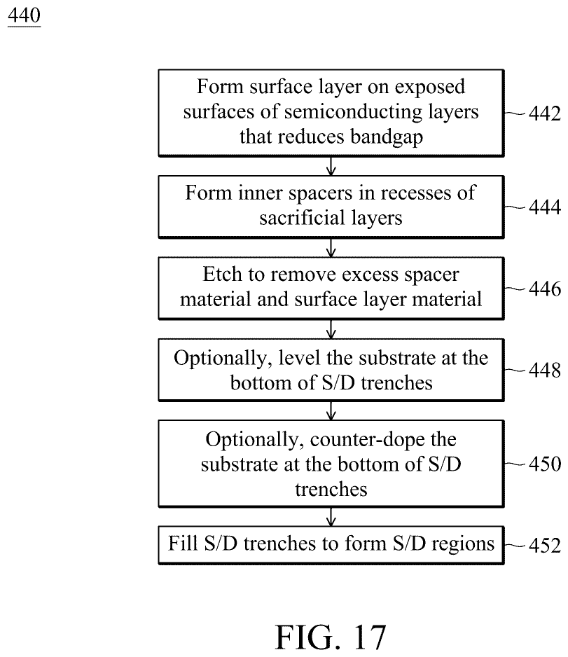

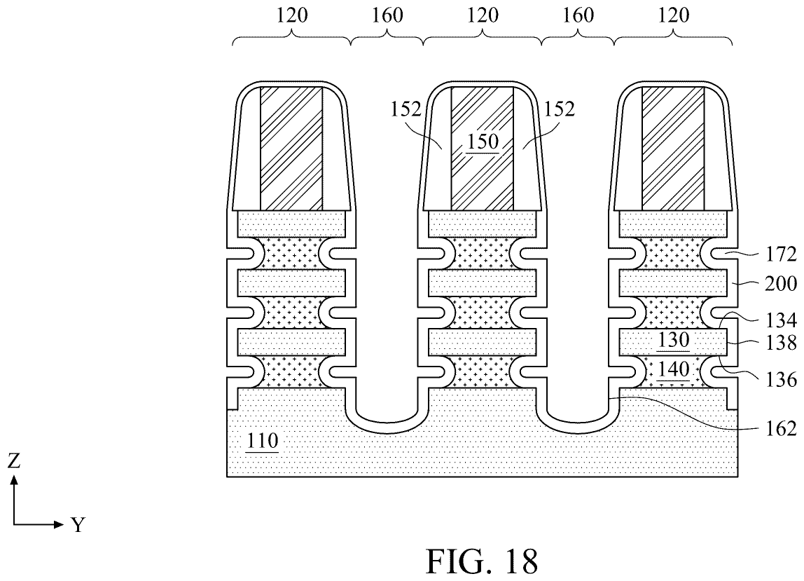

FIG. 16A and FIG. 16B are Y-axis cross-sectional views of a third embodiment of a transistor 101 of the present disclosure, in accordance with some embodiments of the present disclosure. Here, surface layers are formed on the semiconducting layers/channels. A magnified cross-sectional view is also present.

Referring first to FIG. 16A, the transistor 101 is illustrated as a GAA transistor. The transistor includes a substrate 110, semiconducting stacks 120 formed by alternating layers of semiconducting layers 130 and sacrificial layers 140, inner spacers 172, dummy gates 150, gate spacers 152, a leveled substrate 110, and S/D regions 170 as previously described. The surface layers 200 are shown as surrounding three sides of the inner spacers 172 and contacting the sacrificial layers 140. The surface layer is missing from the side of the inner spacers that contacts the S/D regions 170. Surface layers are present along upper surfaces 134 and lower surfaces 136 of the semiconducting layers.

Referring to the magnified view, generally, in particular embodiments, the surface layer 200 may have a thickness 205 of about 0.5 nanometers to about 2 nanometers. Other values and ranges are also within the scope of this disclosure. As illustrated here, the upper surface 134 and the lower surface 136 of the end of the semiconducting layer 130 are in direct contact with the surface layer 200. In addition, the sacrificial layer 140 directly contacts the surface layer 200. The surface layer is not located between the inner spacer 172 and the S/D region 170.

In FIG. 16B, the surface layers 200 are shown as being present only along the upper surfaces 134 and lower surfaces 136 of the semiconducting layers. The surface layer does not contact the sacrificial layers 140. The surface layer is also missing from the side of the inner spacers that contacts the S/D regions 170.

In these embodiments, the surface layers 200 comprise a material that reduces the bandgap of the semiconducting layers. For example, the bandgap of silicon is 1.1 eV at room temperature. The surface layer material lowers the bandgap below 1.1 eV, increasing the mobility of the semiconducting layer. It is noted that although illustrated as a separate layer, this is for ease of representation, and in the actual device the surface layer may be considered part of the semiconducting layer 130 as well. Examples of suitable materials for this surface layer include elements in Group 13 and 15 of the periodic table, such as germanium, gallium arsenide (GaAs), gallium nitride (GaN), gallium-antimony (GaSb), indium arsenide (InAs), indium phosphide (InP), and indium-antimony (InSb).

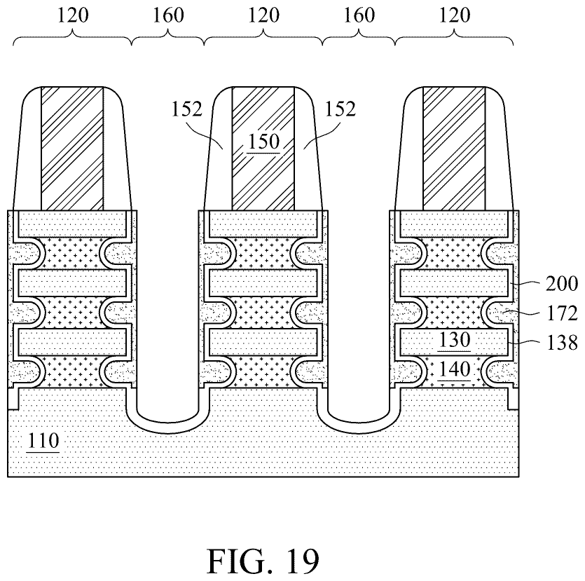

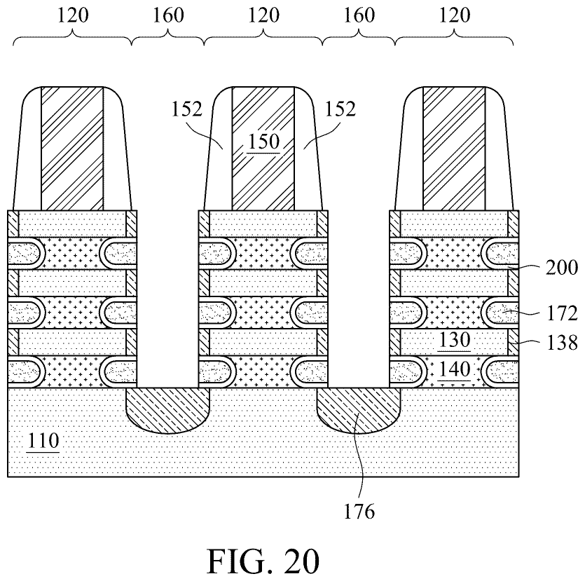

FIG. 17 is a flow chart illustrating another method 440 for making a transistor, in accordance with some embodiments. In particular, a GAA transistor is made in which surface layers are formed on the semiconducting layers. The method starts with the intermediate structure of FIG. 3 and FIG. 4, and some steps of the method are also illustrated in FIGS. 18-23. These figures provide different views for better understanding. While the method steps are discussed below in terms of forming a single transistor, such discussion should also be broadly construed as applying to the concurrent formation of multiple structures, and can be suitably adapted to form other transistors or devices. Other structures may also be concurrently formed. It is noted that not all steps described in the flow chart are required, and not all method steps are described in the flow chart.

Initially, in step 442 of FIG. 17 and as illustrated in FIG. 18, surface layers 200 are formed on the exposed surfaces 134, 136, 138 of the semiconducting layers. In this embodiment, this process step may be done, for example, using a thermal annealing treatment in the presence of a gas containing a bandgap-reducing material. For example, a germanium surface layer may be formed using germanium hydride (GeH₄) gas. In particular embodiments, the thermal annealing treatment occurs at a temperature of about 600 °C to about 900 °C, including from about 650 °C to about 750 °C. The thermal annealing treatment may be performed for a time period ranging from about 20 seconds to about 2 minutes. Other values and ranges for these parameters are also within the scope of this disclosure. As illustrated here, the surface layers 200 are formed as a thin film on the upper surface 134, lower surface 136, and side surfaces 138 at the ends of the semiconducting layers 130. The surface layers 200 are also formed on the other exposed surfaces, including over the gate spacers 152, the sacrificial layers 140, and the lower surfaces 162 of the S/D trenches 160.

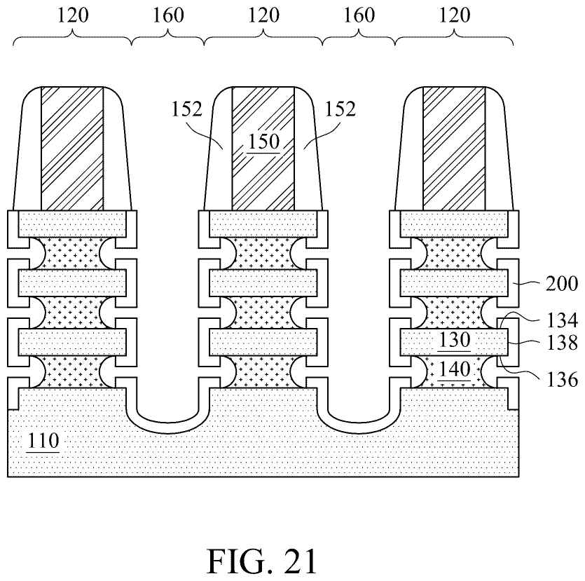

Then, in step 444 of FIG. 17 and as illustrated in FIG. 19, inner spacers 172 are formed within the recesses in the sacrificial layers 140. The inner spacers are formed from a dielectric material and may be formed by any suitable deposition process, such as ALD. As illustrated here, the material used to form the inner spacers also covers the sides 138 of the semiconductor layers.

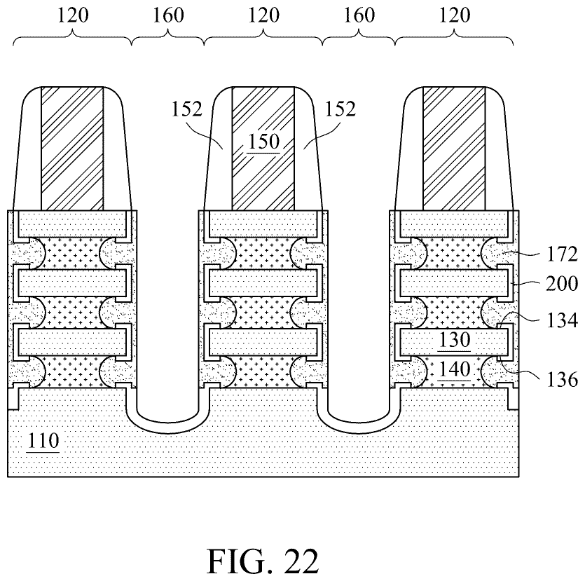

Next, in step 446 of FIG. 17 and as illustrated in FIG. 20, etching is performed within the S/D trenches 160 to remove excess inner spacer material and surface layer material from the surfaces 138 of the semiconducting layers within the S/D trenches 160. This may be done, for example, by etching or other suitable process.

If desired, in optional step 448 of FIG. 17 and as illustrated in FIG. 20, the substrate may be leveled at the bottom of the S/D trenches 160 as previously described. The material used to level the substrate is indicated as base layer 176. In optional step 450, the substrate 110 may be counter-doped at the bottom of the S/D trenches 160. Again, these two steps may be performed concurrently if desired, for example by epitaxy in the presence of a third gas containing the counter-dopant and a fourth gas that contains silicon (or other appropriate material for the substrate). The structure of FIG. 20 is not counter-doped.

Finally, in step 452 of FIG. 17, the S/D trenches are filled to form S/D regions 170. This is typically done by epitaxy in the presence of a fifth gas containing a dopant and a sixth gas that contains silicon (or other appropriate material for forming an electrode). The resulting structure is shown in FIG. 16A.

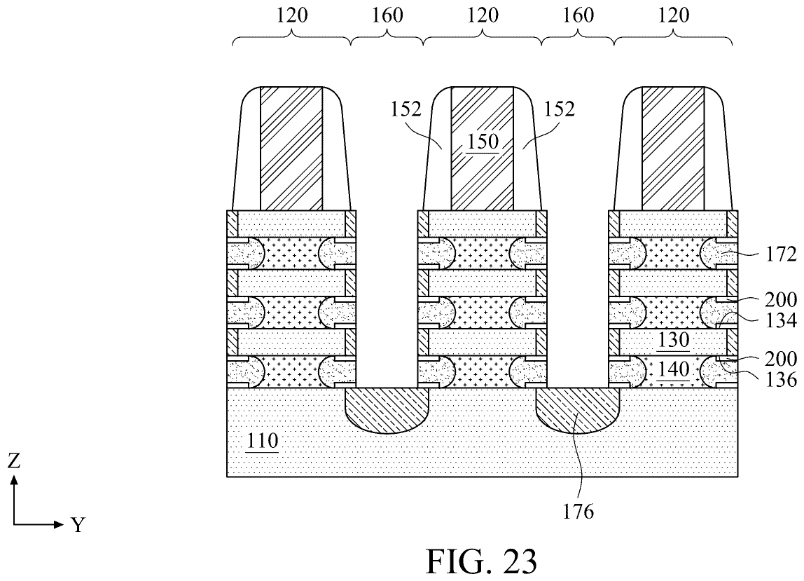

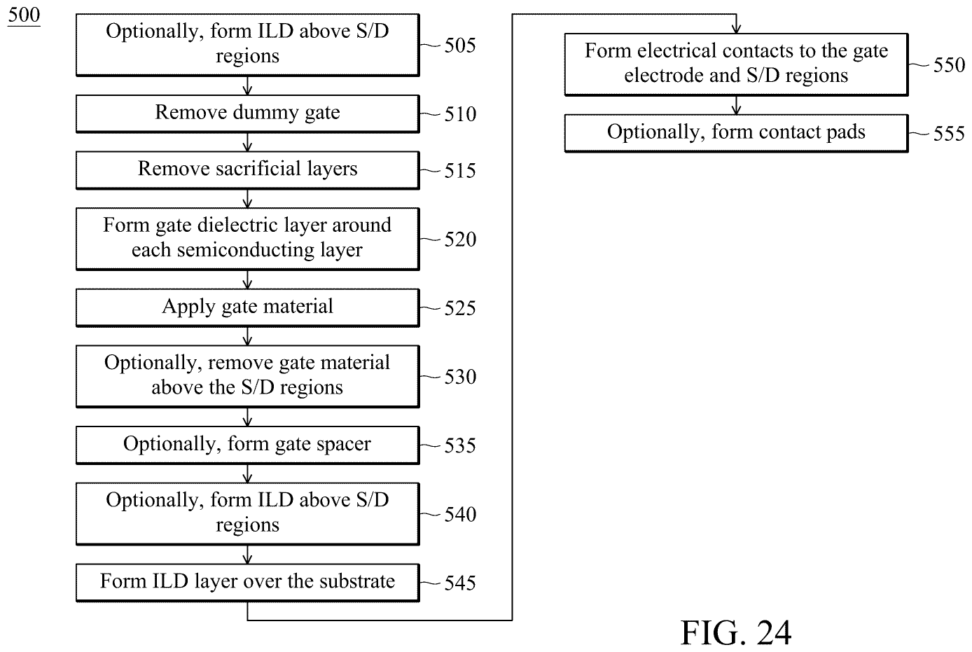

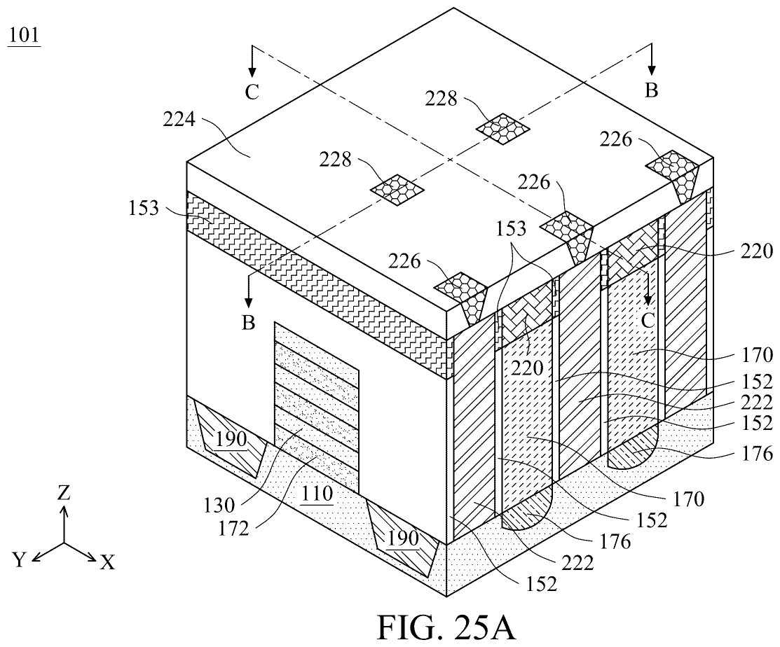

As an alternative, and as illustrated in FIG. 21, in step 442 of FIG. 17, the surface layers 200 may be formed on the exposed surfaces 134, 136, 138 of the semiconducting layers by epitaxy. The epitaxy may be performed in the presence of a seventh gas that contains silicon (or other appropriate material for the substrate) and one or more gases for forming the surface layer. The surface layers are thus formed only on the exposed surfaces of the semiconducting layers and the substrate in the S/D trenches, and not on the sacrificial layers 140. FIG. 22 illustrates the structure after step 444, and FIG. 23 illustrates the structure after step 450. As seen there, the etching results in the surface layers 200 only being present on the upper surface 134 and lower surface 136 of the semiconducting layers 130. After step 452 is performed, the resulting structure is shown in FIG. 16B.

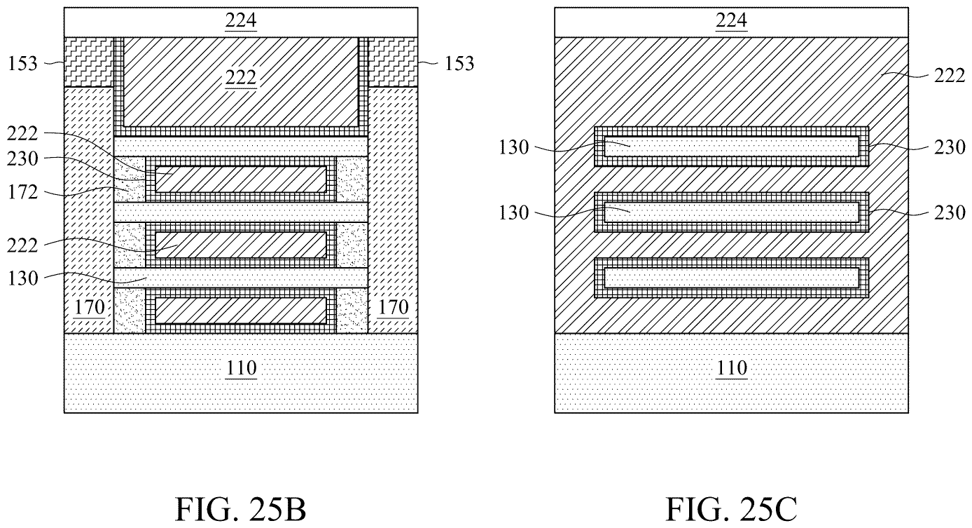

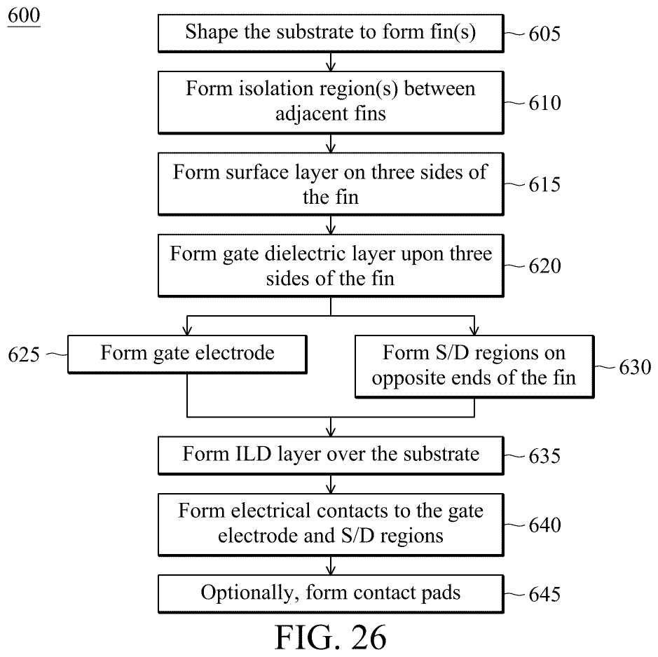

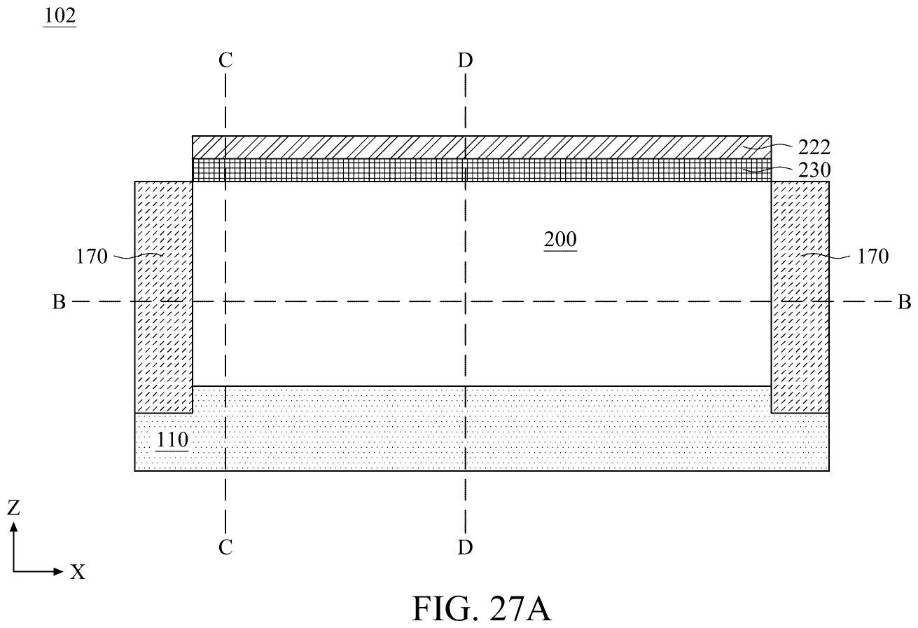

FIG. 24 is a flow chart illustrating a method 500 for completing the formation of a Gate-All-Around (GAA) transistor 101, in accordance with some embodiments. It is contemplated that these steps are performed after the intermediate transistor structure is processed using the process steps of FIG. 5, or FIG. 12, or FIG. 17. The method is also described with reference to FIGS. 25A-25C. While the method steps are discussed below in terms of forming a single transistor, such discussion should also be broadly construed as applying to the concurrent formation of multiple structures, and can be suitably adapted to form other transistors or devices. Other structures may also be concurrently formed. It is noted that not all steps described in the flow chart are required, and not all method steps are described in the flow chart.

Initially, it should be noted that when considering the perspective view of FIG. 3 together with the cross-sectional view of, for example, FIG. 23, the S/D regions 170 are separated from the dummy gates 150 by the gate spacers 152. The dummy gates are removed and replaced with a gate electrode. This can be done in at least two different ways.

In one process, in step 505 of FIG. 24 and referring to FIG. 23 and FIG. 25A, an interlayer dielectric (ILD) 220 is formed over the source/drain regions 170. Then, in step 510, the dummy gates 150 are removed. These steps can be performed by wet etching, dry etching, or chemical-mechanical planarization (CMP) as desired or appropriate. If the optional dummy gate oxide layer is present, it can be used as an etch stop layer for the other layers, and then itself etched and removed.

With the dummy gates removed, the sacrificial layers are now exposed along the X-axis. Continuing, in step 515, the sacrificial layers 140 are removed. The semiconducting layers 210 are supported at their ends, and the rest of their surface is exposed. In step 520, a gate dielectric layer 230 is formed around each semiconducting layer 130. The gate dielectric layer can be made of any dielectric material, and may also be a high-k dielectric material as previously described. This may be done using any deposition process as previously described. Next, in step 525 of FIG. 24, a gate material is deposited upon the substrate in the volume previously filled by the dummy gate to form gate electrodes 222. The gate electrodes 130 surround the gate dielectric layers 230 and the semiconducting layers 130. Referring to FIG. 25, each gate electrode 222 has a gate spacer 152 and an S/D region 170 on each side thereof. The gate electrode can be a multi-layered structure to tune the properties of the gate terminal as desired. The gate electrode can be formed using ALD, CVD, sputtering, or the like.

The top surface of the ILDs 220 and the gate electrodes 222 can be planarized to remove excess material. Continuing, then, in step 545 of FIG. 24 and as illustrated in FIG. 25, an ILD layer 224 is formed over the substrate. The ILD layer 224 covers both the gate electrodes 222 and the S/D regions 170. In step 550, electrical contacts 226, 228 are formed to the gate electrodes 222 and the S/D regions 170. This can be done, for example, by etching through the ILD layer 224 to form via openings and then filling the via openings with an electrically conductive metal. As illustrated here, the gate contacts 226 are offset from the S/D contacts 228 along the X-axis. If desired, in optional step 555, contact pads are formed. This may be done by applying a second ILD layer, etching above the electrical contacts 226, 228, and then filling to form the contact pads electrically connected to the contacts.

In the second process, starting with step 510 of FIG. 24 and referring to FIG. 23 and FIG. 25, the dummy gates 150 are removed. Again, this exposes the sacrificial layers 140 and the semiconducting layers 130. Then, in step 515, the sacrificial layers 140 are removed. In step 520, a gate dielectric layer is formed around each semiconducting layer. Next, in step 525 of FIG. 24, a gate material is deposited upon the substrate.

In this second process, the gate material fills the volume previously filled by the dummy gate to form gate electrodes, and also covers the S/D regions 170. Thus, in step 530 of FIG. 24, the gate material is removed from above the S/D regions. In step 535 and as seen in FIG. 25A, additional gate spacers 153 are formed upon the exposed surfaces of the gate electrodes 222. Then, in step 540, the ILDs 220 are formed above the S/D regions 170. Steps 545-555 may be performed as previously described.

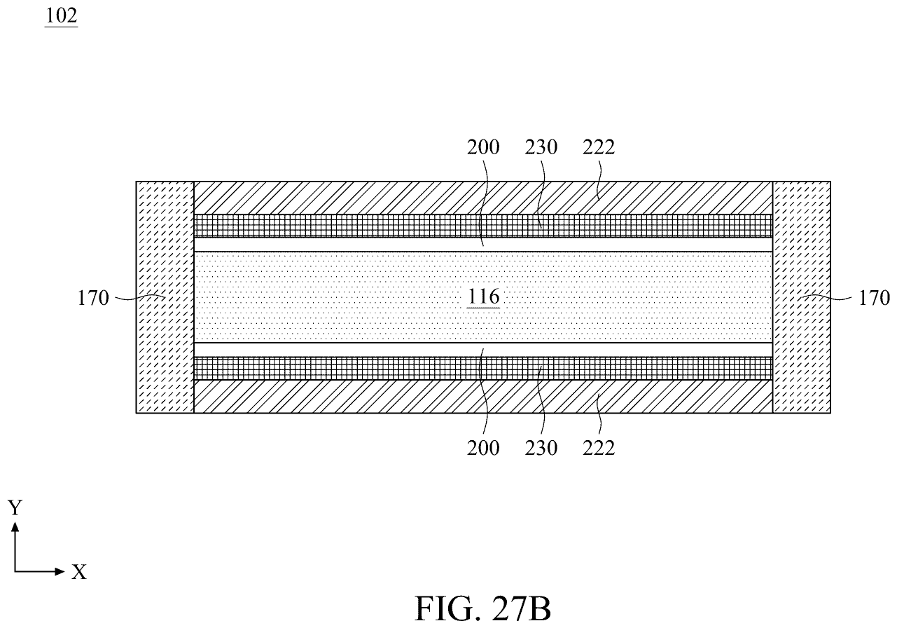

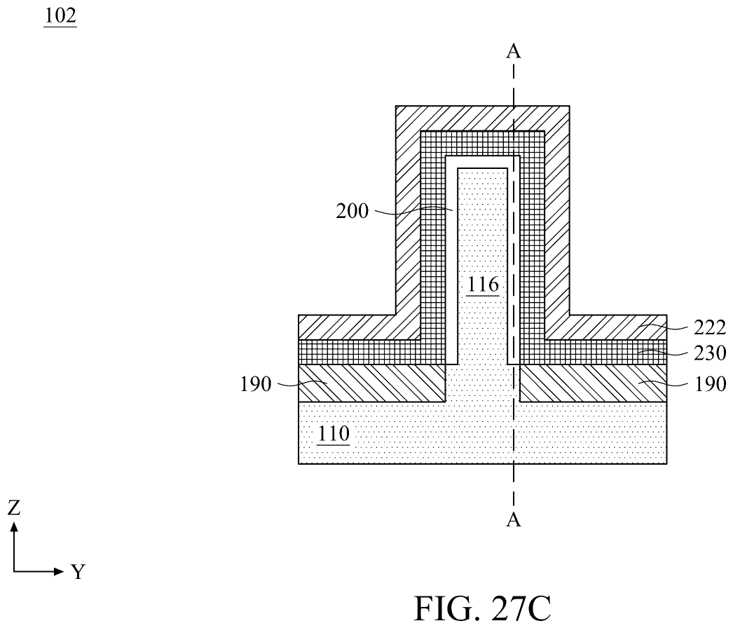

Although illustrated above with respect to a GAA transistor, the caps/surface layers described above are also applicable to other transistors. FIG. 26 is a flow chart illustrating a method 600 for making a FinFET (fin field effect transistor) 103 with a three-dimensional structure, in accordance with some embodiments. The method is described with reference to the final structure illustrated in FIGS. 27A-27C, for better understanding. FIG. 27A is a Y-axis cross-sectional view of the FinFET through line A-A of FIG. 27C. FIG. 27B is a Z-axis plan view of the FinFET through line B-B of FIG. 27A. FIG. 27C is an X-axis cross-sectional view of the FinFET through line C-C and line D-D of FIG. 27A. Again, such discussion should also be broadly construed as applying to the concurrent formation of multiple structures. Other structures may also be concurrently formed. Not all steps described in the flow chart are required, and not all method steps are described in the flow chart.

Initially, in step 605, the substrate 110 is shaped to form one or more fins 116. Typically, one or more hardmask layers is/are applied to the substrate. Mandrels are then formed upon the hardmask layer(s) over the substrate. This can be done by depositing a mandrel material layer, forming a photoresist layer upon the mandrel material layer, exposing the photoresist to radiation and developing the photoresist layer to form a mandrel pattern, and then etching the mandrel material layer to form the mandrels. If desired, the mandrels are then used as a mask, and etching is performed through the hardmask layer(s) and into the substrate is performed to form the fins. Alternatively, in a process known as self-aligned double patterning (SADP), spacers are formed on the sidewalls of the mandrels, and the mandrels are then removed. The spacers are then used as a mask, and etching is performed through the hardmask layer(s) and into the substrate is performed to form the fins. Self-aligned quadruple patterning (SAQP) is a similar process, and can also be used to form the fins.

Many of the following steps are the same as those previously described, suitably modified for a FinFET. In step 610 of FIG. 26, isolation regions 190 are formed between adjacent fins. In step 615, a surface layer 200 is formed on three sides of the fin 116. This is most easily seen in FIG. 27C. The surface layer may include a p-type dopant or an n-type dopant as illustrated in FIG. 1, a polar compound as illustrated in FIGS. 11B-11C, a material having a net positive or negative charge as illustrated in FIGS. 11D-11E, or a bandgap-reducing material as illustrated in FIGS. 16A-16B.

Next, in step 620 of FIG. 26, a gate dielectric layer 230 is formed upon three sides of the fin. In step 625, a gate electrode 222 is formed over the gate dielectric layer. Then, in step 630, S/D regions 170 are formed on opposite ends of the fin, on opposite sides of the gate electrode 222. Steps 625 and 630 can be performed in either order. The resulting structure is shown in FIG. 27.

Additional process steps may also be performed to package the FinFET. In step 635 of FIG. 26, an ILD layer may be formed over the substrate. In step 640, electrical contacts are formed to the gate electrodes 222 and the S/D regions 170. If desired, in optional step 645, contact pads are formed. These steps may be done as previously described.

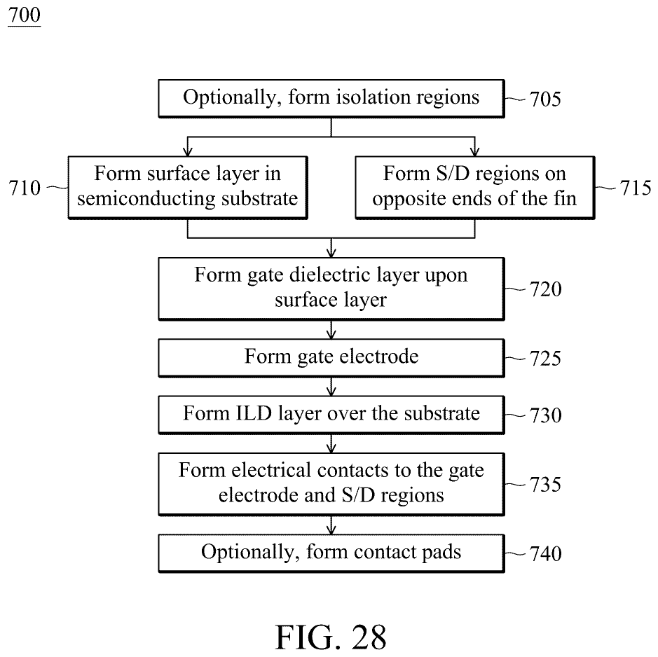

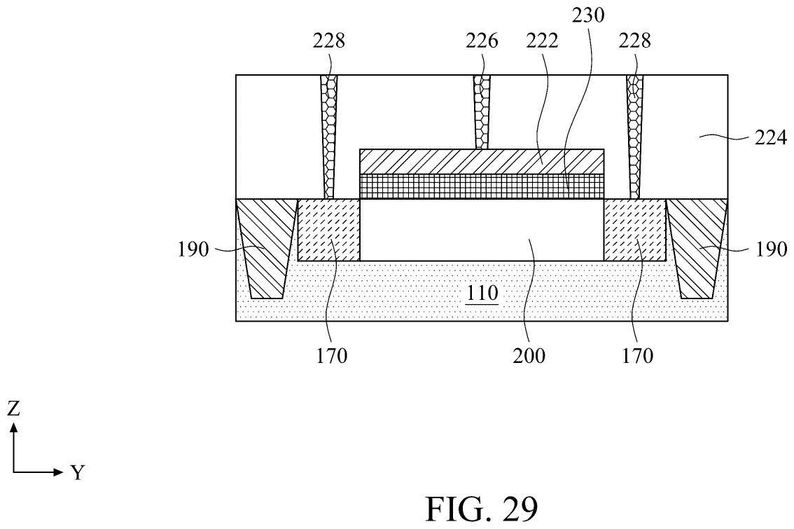

FIG. 28 is a flow chart illustrating a method 700 for making a planar transistor 104 having a surface layer, in accordance with some embodiments. The method is described with reference to the final structure illustrated in FIG. 29, which is a top-gate bottom-contact transistor, for better understanding. Again, such discussion should also be broadly construed as applying to the concurrent formation of multiple structures. Other structures may also be concurrently formed. Not all steps described in the flow chart are required, and not all method steps are described in the flow chart.

Again, many of the following steps are the same as those previously described, suitably modified. In step 705 of FIG. 28, isolation regions 190 are formed to define an active region. In step 710, a surface layer 200 is formed in the substrate, which acts as the semiconducting channel between S/D regions. The surface layer may include a p-type dopant or an n-type dopant as illustrated in FIG. 1, a polar compound as illustrated in FIGS. 11B-11C, a material having a net positive or negative charge as illustrated in FIGS. 11D-11E, or a bandgap-reducing material as illustrated in FIGS. 16A-16B. Then, in step 715, S/D regions 170 are formed on opposite sides of the surface layer 200. Steps 710 and 715 can be performed in either order. Next, in step 720 of FIG. 28, a gate dielectric layer 230 is formed over the surface layer. In step 725, a gate electrode 222 is formed over the gate dielectric layer. Additional process steps may also be performed to package the FinFET. In step 730, an ILD layer 224 may be formed over the substrate. In step 735, electrical contacts 226, 228 are formed to the gate electrodes 222 and the S/D regions 170. If desired, in optional step 740, contact pads are formed. These steps may be done as previously described. Top-gate top-contact, bottom-gate bottom-contact, and bottom-gate top-contact transistors may also be formed, with the method being suitably modified by changing the order of the steps and the resulting relative placement of the various components.

The transistors and methods of the present disclosure include several different dielectric structures. Such dielectric structures can generally be made from any suitable combination of dielectric materials, although the characteristics of any particular layer may also be further defined. Examples of dielectric materials may include silicon dioxide (SiO₂), silicon nitride (Si₃N₄, abbreviated SiN), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

It is also noted that certain conventional steps are not expressly described in the discussion above. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90 °C to about 110 °C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

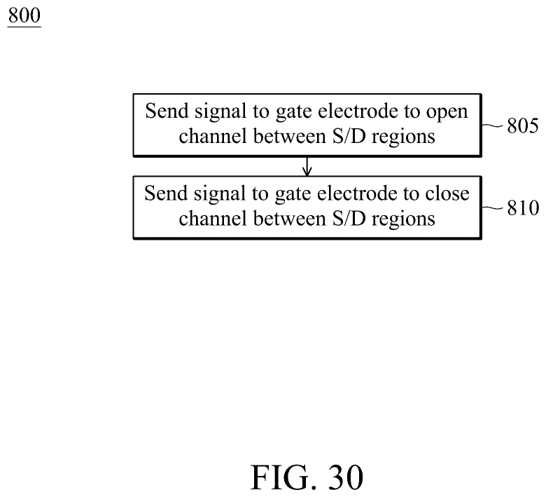

FIG. 30 is a flow chart illustrating a method 800 for operating a transistor, in accordance with some embodiments. The method steps are discussed below in terms of using a single transistor, and should also be broadly construed as applying to the concurrent use of multiple transistors. Reference is also made to the planar transistor of FIG. 29, although this method applies generally to all transistors.

In step 805 of FIG. 30, a signal is sent to a gate electrode 222. Typically, a voltage signal is sent, either in the form of an increased voltage or a decreased voltage (depending on how the gate electrode is operated). This opens a channel between the S/D regions/electrodes 170, which permits current to flow between them. The current also flows through the surface layer 200. In step 810, a different signal is sent to the gate electrode 222 to close the channel.

Integrated circuits containing the semiconductor devices/transistors illustrated herein may be used in various applications. Those integrated circuits might include central processing units (CPUs), graphics processing units (GPUs), graphics integrated circuits, and/or server or power management integrated circuits. Various devices that include such integrated circuits or semiconductor devices might include those such as image signal processors (ISP), which can be combined with CMOS image sensors; or global shutters for high speed capture in a camera or monitor. Other potential applications might include BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or artificial intelligence applications.

The structures of the present disclosure have several advantages. Junction overlap variation caused by instability in the etching process is mitigated. The junction can also be self-aligned. Dopant fluctuation is less random. Control of short-channel effects is improved due to junction abruptness. A smaller bandgap can reduce resistance and reduce parasitic capacitance.

Some embodiments of the present disclosure thus relate to methods for making a transistor, especially a GAA transistor. A cap is formed on exposed surfaces of semiconducting layers in a semiconducting stack. The cap comprises an n-type dopant or a p-type dopant. Inner spacers are formed between adjacent semiconducting layers in the semiconducting stack. S/D trenches on opposite sides of the semiconducting stack are then filled to form S/D regions.

Other embodiments disclosed herein relate to other methods for making a transistor, especially a GAA transistor. A surface layer is formed on exposed surfaces of semiconducting layers in a semiconducting stack. Inner spacers are formed between adjacent semiconducting layers in the semiconducting stack. S/D trenches on opposite sides of the semiconducting stack are filled to form S/D regions. The surface layer comprises a polar compound, or comprises a material having a net positive or negative charge, or comprises a material that reduces a bandgap of the semiconducting layers.

Also described in various embodiments herein are GAA transistors that comprise a semiconducting stack, S/D regions, gate dielectric layers, and a gate electrode. The semiconducting stack comprises a plurality of semiconducting layers, wherein adjacent semiconducting layers are separated by an inner spacer. A surface layer is present between each adjacent semiconducting layer and inner spacer. The surface layer comprises an n-type dopant or a p-type dopant, or comprises a polar compound, or comprises a material having a net positive or negative charge, or comprises a material that reduces a bandgap of the adjacent semiconducting layer. The S/D regions are located on opposite sides of the semiconducting stack. A gate dielectric layer surrounds each semiconducting layer. The gate electrode contacts the gate dielectric layers.

The present disclosure also relates in various embodiments to methods for making a FinFET. A substrate with at least one fin is received, or is formed. Isolation regions are formed on either side of the at least one fin. A surface layer is formed on the at least one fin. The surface layer comprises an n-type dopant or a p-type dopant, or comprises a polar compound, or comprises a material having a net positive or negative charge, or comprises a material that reduces a bandgap of the at least one fin. S/D regions are formed at opposite ends of the at least one fin. A gate dielectric layer is formed over the at least one fin. A gate electrode is formed over the gate dielectric layer. An ILD layer may be formed over the substrate. Electrical contacts may be formed to the gate electrode and the S/D regions. Optionally, contact pads may be formed upon the electrical contacts.

Some further embodiments of the present disclosure also relate to a FinFET, comprising a substrate, a surface layer, a gate dielectric layer, and S/D regions. The substrate has at least one fin. The surface layer is on the at least one fin. The surface layer comprises an n-type dopant or a p-type dopant, or comprises a polar compound, or comprises a material having a net positive or negative charge, or comprises a material that reduces a bandgap of the at least one fin. A gate dielectric layer is located over the at least one fin. A gate electrode is located over the gate dielectric layer. S/D regions are present at opposite ends of the at least one fin.

The present disclosure also relates in various embodiments to methods for making a planar transistor. Isolation regions may be formed in a substrate to define an active region. A surface layer in the active region is then formed in the active region. The surface layer comprises an n-type dopant or a p-type dopant, or comprises a polar compound, or comprises a material having a net positive or negative charge, or comprises a material that reduces a bandgap of the at least one fin. A gate dielectric layer is formed upon the surface layer. A gate electrode is formed over the gate dielectric layer. If desired, a gate spacer may be formed around the gate electrode. S/D regions are formed in the substrate on opposite sides of the gate electrode. An ILD layer may be formed over the substrate. Electrical contacts may be formed to the gate electrode and the S/D regions. Optionally, contact pads may be formed upon the electrical contacts. Planar transistors having such surface layers are also disclosed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for making a semiconductor device, comprising:
forming a cap on exposed surfaces of semiconducting layers in a semiconducting stack, wherein the cap comprises an n-type dopant or a p-type dopant;
forming inner spacers between adjacent semiconducting layers in the semiconducting stack; and
filling S/D trenches on opposite sides of the semiconducting stack to form S/D regions.

2. The method of claim 1, wherein the cap is formed by epitaxy or thermal treatment using a first gas containing silicon and a second gas containing the n-type dopant or the p-type dopant.

3. The method of claim 1, wherein the epitaxy or the thermal treatment is performed at a temperature of about 600 °C to about 900 °C.

4. The method of claim 1, further comprising counter-doping an exposed substrate in the S/D trenches before filling the S/D trenches.

5. The method of claim 1, wherein the cap has a thickness of about 0.5 nanometers to about 2 nanometers.

6. A method for making a semiconductor device, comprising:
forming a surface layer on exposed surfaces of semiconducting layers in a semiconducting stack;
forming inner spacers between adjacent semiconducting layers in the semiconducting stack; and
filling S/D trenches on opposite sides of the semiconducting stack to form S/D regions;
wherein the surface layer comprises a polar compound, or comprises a material having a net positive or negative charge, or comprises a material that reduces a bandgap of the semiconducting layers.

7. The method of claim 6, wherein the surface layer comprises the polar compound and is formed by CVD or ALD.

8. The method of claim 6, wherein the polar compound is an oxide or a nitride.

9. The method of claim 8, wherein the polar compound comprises aluminum, zinc, titanium, boron, gallium, indium, or thallium.

10. The method of claim 8, wherein the polar compound comprises a lanthanide.

11. The method of claim 6, wherein the material having a net positive or negative charge comprises silicon, boron, aluminum, gallium, indium, or thallium, and is a nitride, oxynitride, or carboxynitride.

12. The method of claim 6, wherein the material having a net positive or negative charge comprises a lanthanide and is a nitride, oxynitride, or carboxynitride.

13. The method of claim 6, wherein the material that reduces a bandgap comprises germanium, boron, aluminum, gallium, indium, or thallium, nitrogen, phosphorus, arsenic, antimony, bismuth, and compounds thereof.

14. The method of claim 6, wherein the surface layer is formed by epitaxy or by thermal annealing in a gas.

15. The method of claim 6, wherein the surface layer has a thickness of about 0.5 nanometers to about 2 nanometers.

16. The method of claim 6, further comprising depositing a material into the S/D trenches to level the substrate prior to filling the S/D trenches.

17. A semiconductor device, comprising:
a semiconducting stack comprising:
a plurality of semiconducting layers, wherein adjacent semiconducting layers are separated by an inner spacer; and
a surface layer between each adjacent semiconducting layer and inner spacer, wherein the surface layer comprises an n-type dopant or a p-type dopant, or comprises a polar compound, or comprises a material having a net positive or negative charge, or comprises a material that reduces a bandgap of the adjacent semiconducting layer; and
S/D regions on opposite sides of the semiconducting stack;
gate dielectric layers surrounding each semiconducting layer; and
a gate electrode contacting the gate dielectric layers.

18. The semiconductor device of claim 17, further comprising a counter-doped base layer below each S/D region.

19. The semiconductor device of claim 17, further comprising an interlayer dielectric above each S/D region.

20. The semiconductor device of claim 17, wherein each surface layer has a thickness of about 0.5 nanometers to about 2 nanometers.
